(19) United States
(12) Patent Application Publication
(10) Pub. No.: US 2025/0133800 A1
(43) Pub. Date: Apr. 24, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Hwei-Jay CHU, Hsinchu (TW); Hsi-Wen TIEN, Hsinchu (TW); Wei-Hao LIAO, Hsinchu (TW); Yu-Teng DAI, Hsinchu (TW); Hsin-Chieh YAO, Hsinchu (TW); Chih-Wei LU, Hsinchu (TW); Cheng-Hao CHEN, Hsinchu (TW)

(73) Assignee: Taiwan Semiconductor Manufacturing Company, Ltd., Hsinchu (TW)

(21) Appl. No.: 18/381,555

(22) Filed: Oct. 18, 2023

(51) Int. Cl. H01L 29/66; H01L 21/768; H01L 21/8234; H01L 23/528; H01L 27/088

(52) U.S. Cl. CPC H10D 64/021; H01L 21/7682; H01L 21/76832; H01L 21/76843; H01L 21/76877; H01L 23/5283; H10D 84/0149; H10D 84/038; H10D 84/83

(57) ABSTRACT

A semiconductor device includes a MEOL structure and a BEOL structure. The BEOL structure is formed over the MEOL structure and includes a first dielectric layer, a spacer and a conductive portion. The first dielectric layer has a lateral surface and a recess, wherein the recess is recessed with respect to the lateral surface. The spacer is formed the lateral surface and covers an opening of the recess. The conductive portion is formed adjacent to the spacer.

### BACKGROUND

In small pitch pattern, the parasitic capacitance effect is more critical due to the very small distance between two metal lines (or space width between metal lines), which will reduce the electrical performance and the reliability with the increasing propagation delay and the extra noise source.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device according to an embodiment of the present disclosure;

FIG. 2 illustrates a cross-sectional view of a semiconductor device according to an embodiment of the present disclosure;

FIGS. 3A_a to 3H illustrate schematic diagrams of manufacturing processes of the semiconductor device in FIG. 1; and

FIGS. 4A_a to 4H illustrate schematic diagrams of manufacturing processes of the semiconductor device in FIG. 2.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

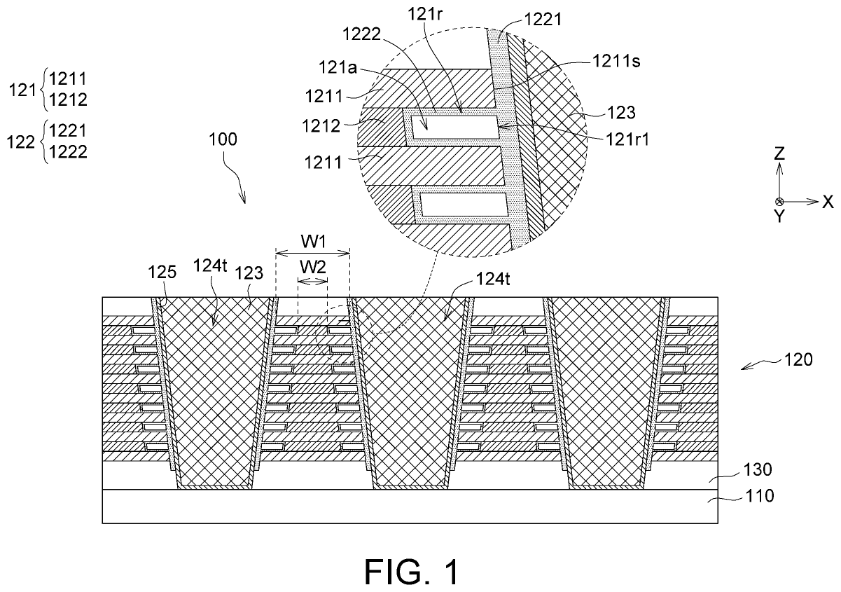

Referring to FIG. 1, FIG. 1 illustrates a cross-sectional view of a semiconductor device 100 according to an embodiment of the present disclosure. The semiconductor device 100 includes a MEOL (Middle End of Line) structure 110, a BEOL (Back End of Line) structure 120 and a first etching stop layer (ESL) 130.

As illustrated in FIG. 1, the BEOL structure 120 is formed over the MEOL structure 110. The BEOL structure 120 includes at least one first dielectric layer 121, at least one spacer 122, at least one conductive portion (for example, M1 metal) 123, at least trench 124t and at least one barrier 125. The first dielectric layer 121 has a lateral surface 1211s and a recess 121r, wherein the recess 121r is recessed with respect to the lateral surface 1211s. The spacer 122 is formed the lateral surface 1211s and covers an opening 121r1 of the recess 121r. The conductive portion 123 is formed adjacent to the spacer 122. Due to the opening 121r1 being closed (or sealed), the recess 121r forms a closed air gap (or a layered air-gap) 121a. The air gap 121a may increase an electrical isolation between two components, for example, transistors, conductive vias, etc. In addition, in comparison with the conventional structure, the air gap 121a in the present embodiment may reduce parasitic capacitance, and accordingly it may obtain better electrical performance (such as better reliability, reducing propagation delay and extra noise, etc.).

In an embodiment, the air gap 121a is formed before the conductive portion 123 is formed, and thus the conductive portion 123 is not damaged by process of forming the air gap 121a.

As illustrated in FIG. 1, each air gap 121a extends in a first direction (for example, in X axis) and a plurality of the air gap 121a are arranged in a second direction (for example, in Z axis) perpendicular to the first direction. The spacer 122 is formed on the lateral surface 1211s and closes each air gap 121a.

Although not illustrated, the semiconductor device 100 further includes a FEOL (Front End of Line) structure formed under the MEOL structure 110. The MEOL structure 110 may include, for example, a conductive portion (for example, Metal 0 (M0)), a dielectric layer, etc. Alternatively, the semiconductor device 100 further includes the M0 formed between the MEOL structure 110 and the first etching stop layer 130. The M0 may be electrically connected with the MEOL structure. The MEOL structure 110 is electrically connected with the FEOL structure, and the BEOL structure 120 is electrically connected with the MEOL structure 110 through the conductive portion 123.

As illustrated in FIG. 1, the first dielectric layer 121 includes a plurality of first sub-dielectric layers 1211 and at least one second sub-dielectric layer 1212. The second sub-dielectric layer 1212 is formed between adjacent two of the first sub-dielectric layers 1211. The recess 121r extends to the second sub-dielectric layer 1212 from the lateral surfaces 1211s of adjacent two of the first sub-dielectric layers 1211.

In an embodiment, each first sub-dielectric layer 1211 is formed from a material different from that of the second sub-dielectric layer 1212. Due to the different material, the recess 121r may be formed in the second sub-dielectric layer 1212 through different etching selectivity ratios. In an embodiment, the first sub-dielectric layer 1211 may be formed of one of SiC, SiO₂, SiOC, SiN, SiCN, SiON and SiOCN, and the second sub-dielectric layers 1212 may be formed of another of SiC, SiO₂, SiOC, SiN, SiCN, SiON and SiOCN.

As illustrated in FIG. 1, each first sub-dielectric layer 1211 has a first width W1 greater than a second width W2 of the second sub-dielectric layer 1212. Due to the second sub-dielectric layer 1212 being formed between adjacent two of the first sub-dielectric layers 1211, the second width W2 of the second sub-dielectric layer 1212 or the size of the air gap 121a may be precisely controllable by, for example, etching.

As illustrated in FIG. 1, the spacer 122 includes a first covering portion 1221 and at least one second covering portion 1222, wherein the first covering portion 1221 covers the entire lateral surface of each first sub-dielectric layer 1211, and the second covering portion 1222 is formed within the recess 121r and covers the inner sidewall of the recess 121r. The recess 121r which is not covered by the second covering portion 1222 forms the air gap 121a. In addition, the spacer 122 may be formed of a dielectric material the same as that of the first sub-dielectric layer 1211 or the second sub-dielectric layer 1212.

As illustrated in FIG. 1, the conductive portion 123 fills the trench 124t. The conductive portions 123 are separated by at least one air gap 121a. The conductive portion 123 is, for example, metal line. Furthermore, the conductive portion 123 may be formed of a material including Ta, TaN, TiN, Cu, Co, W, Ru, Al, Mo, Ir or a combination thereof.

As illustrated in FIG. 1, the trench 124t passes through the first dielectric layer 121 and extends to the MEOL structure 110, for example, a conductive via of the MEOL structure 110 for being electrically connected with the MEOL structure 110. The barrier 125 is formed between the conductive portion 123 and the spacer 122. The barrier 125 may be formed of metal nitrides, metal carbide, metal oxide, metals or combination thereof. The barrier 125 may have a thickness ranging between 5 Angstrom (Å) to 200 Å.

As illustrated in FIG. 1, the first etching stop layer 130 may protect the MEOL structure 110 located below the first etching stop layer 130 during manufacturing processes. The first etching stop layer 130 is, for example, a M0 ESL. The first etching stop layer 130 may be formed of a material including SiC, SiO₂, SiOC, SiN, SiCN, SION, SiOCN, AlON, AlO or a combination thereof. The first etching stop layer 130 may be formed by, for example, spin on, Chemical Vapor Deposition (CVD), Physical Vapor Deposition (PVD), Atomic Layer Deposition (ALD), etc. at 20° C. to 400° C. In addition, the first etching stop layer 130 has a thickness ranging between 10 Å and 1000 Å.

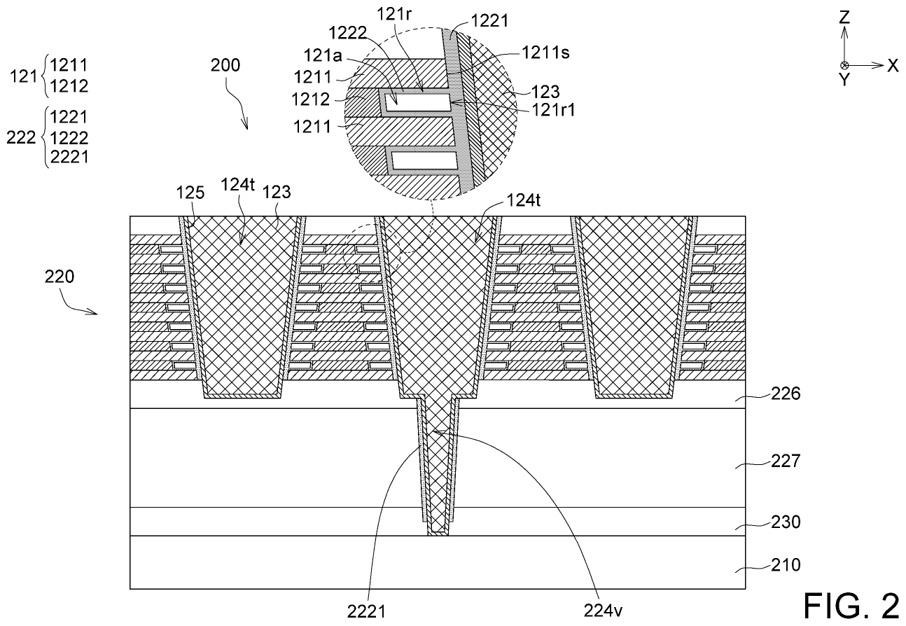

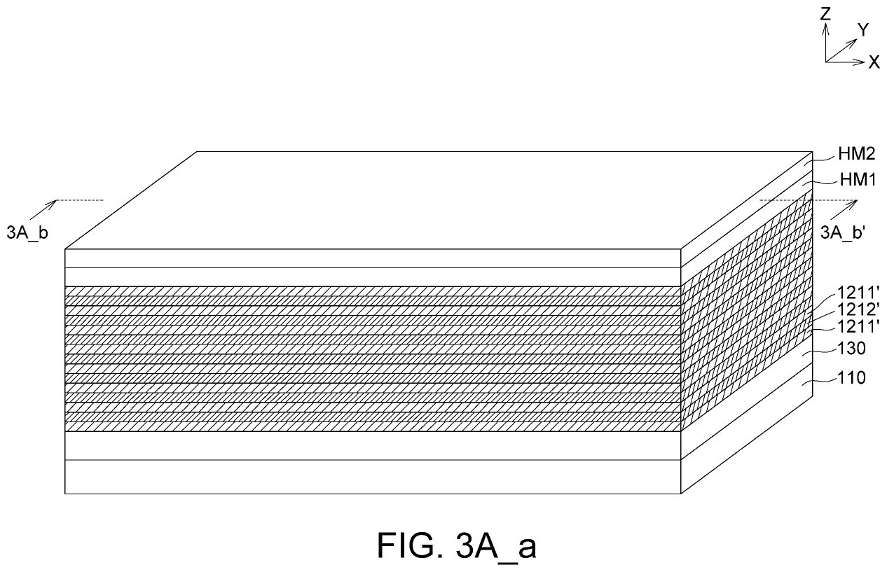

Referring to FIG. 2, FIG. 2 illustrates a cross-sectional view of a semiconductor device 200 according to an embodiment of the present disclosure. The semiconductor device 200 includes a conductive layer 210, the BEOL structure 220 and the first etching stop layer 230. Although not illustrated, the semiconductor device 200 may further include a MEOL structure (which is, for example, the same as or similar to the MEOL structure 110), and the conductive layer 210 is formed above the MEOL structure. In an embodiment, the conductive layer 210 is, for example, M0, and the first etching stop layer 230 is, for example, Metal 1 (M1) ESL. In an embodiment, the conductive layer 210 may be a portion of the MEOL structure.

As illustrated in FIG. 2, the BEOL structure 220 is formed over the conductive layer 210 or the first etching stop layer 230. The BEOL structure 220 includes at least one first dielectric layer 121, at least one spacer 222, at least one conductive portion 123, at least trench 124t, at least one through hole 224v, at least one barrier 125, at least one second etching stop layer 226 and a second dielectric layer 227. In the present embodiment, the first dielectric layer 121, the spacer 222, the conductive portion 123, the trench 124t, the through hole 224v, the barrier 125, the second etching stop layer 226, the second dielectric layer 227 and the first etching stop layer 230 may be applied to M1 structure. In another embodiment, the first dielectric layer 121, the spacer 222, the conductive portion 123, the trench 124t, the through hole 224v, the barrier 125, the second etching stop layer 226, the second dielectric layer 227 and the first etching stop layer 230 may be applied to Mx structure, wherein x is equal to or greater than 2.

As illustrated in FIG. 2, the first dielectric layer 121 has the lateral surface 1211s and the recess 121r, wherein the recess 121r is recessed with respect to the lateral surface 1211s. The spacer 122 is formed the lateral surface 1211s and covers the opening 121r1 of the recess 121r. The conductive portion 123 is formed adjacent to the spacer 122. Due to the opening 121r1 being closed (or sealed), the recess 121r forms a closed air gap (or layered air-gap) 121a. The air gap 121a may increase an electrical isolation between two components, for example, transistors, conductive vias, etc. In addition, in comparison with the conventional structure, the air gap 121a in the present embodiment may reduce parasitic capacitance, and accordingly it may obtain better electrical performance (such as better reliability, reducing propagation delay and extra noise, etc.).

As illustrated in FIG. 2, the spacer 222 includes the first covering portion 1221, the second covering portion 1222 and a third covering portion 2221, wherein the first covering portion 1221 covers the entire lateral surface of each first sub-dielectric layer 1211, and the second covering portion 1222 is formed within the recess 121r and covers the inner sidewall of the recess 121r. The recess 121r which is not covered by the second covering portion 1222 forms the air gap 121a. In addition, the spacer 222 may be formed of a dielectric material the same as that of the first sub-dielectric layer 1211 or the second sub-dielectric layer 1212. The third covering portion 2221 is formed within the through hole 224v and covers an inner sidewall of the through hole 224v. In the present embodiment, the first covering portion 1221 and the third covering portion 2221 are separated from each other.

As illustrated in FIG. 2, the trench 124t passes through the first dielectric layer 121 and the second etching stop layer 226, and the through hole 224v extends from the trench 124t, passing through the second dielectric layer 227 and the first etching stop layer 230, to the conductive layer 210. The conductive portion 123 fills the trench 124t and the through hole 224v for being electrically connected to the conductive layer 210. The second etching stop layer 226 may be formed of a material the same as that of the first etching stop layer 230. The second dielectric layer 227 is formed between the first etching stop layer 230 and the second etching stop layer 226. The second dielectric layer 227 may be formed of a material the same as that of the first sub-dielectric layer 1211 or the second sub-dielectric layer 1212.

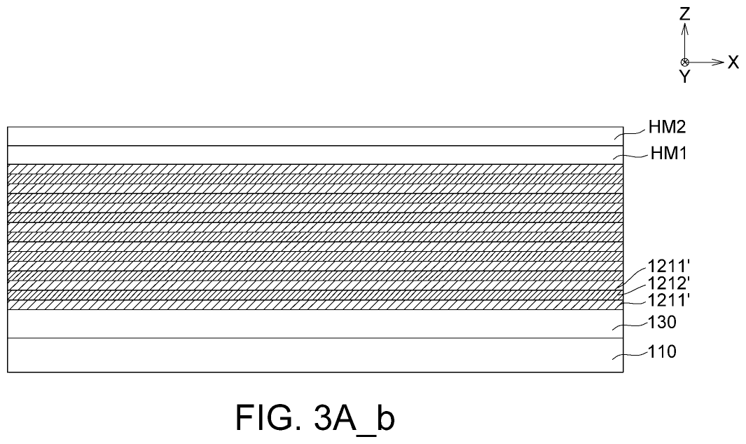

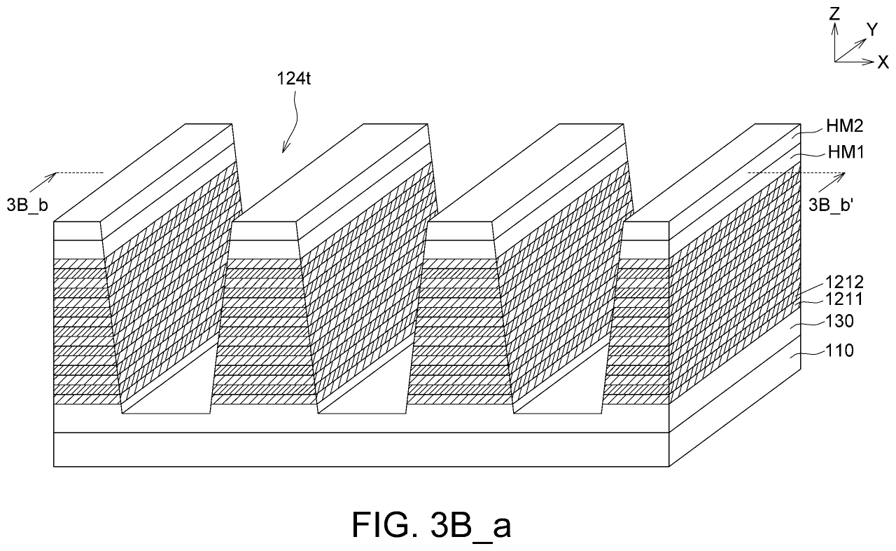

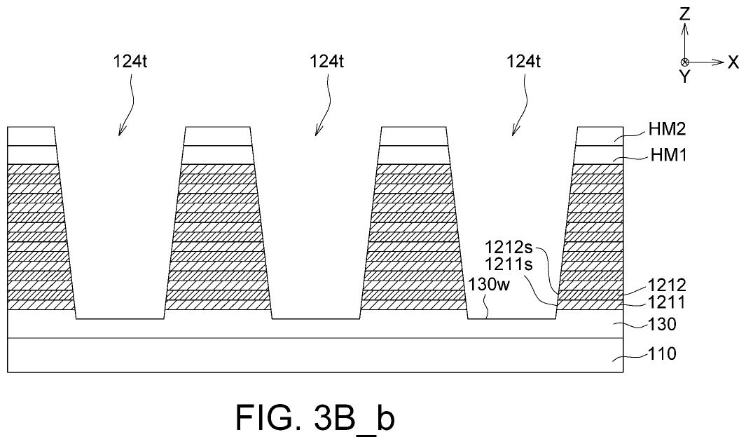

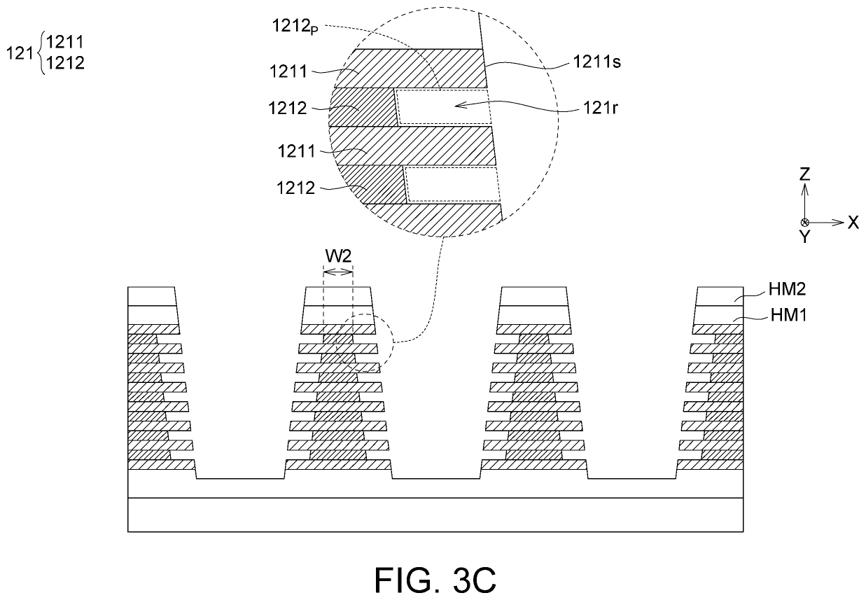

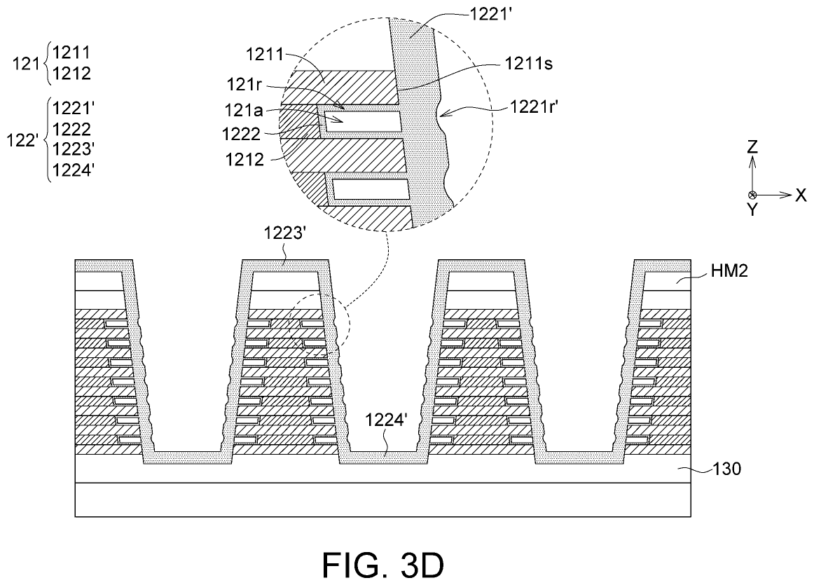

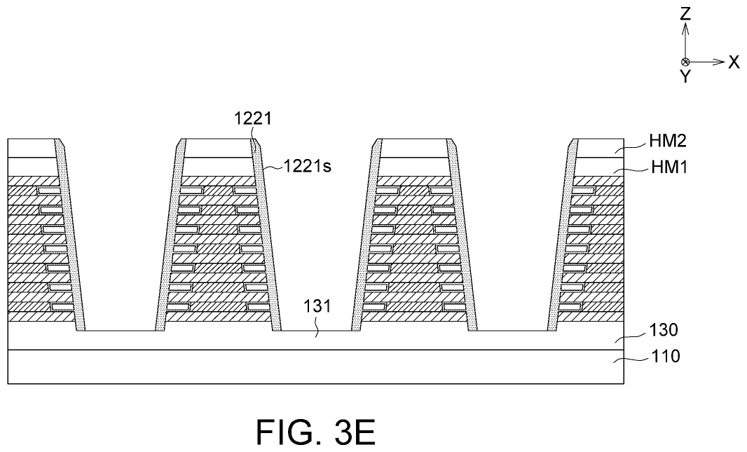

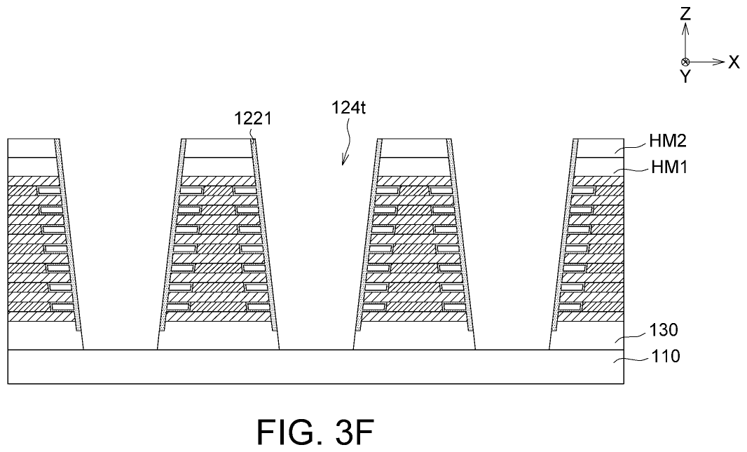

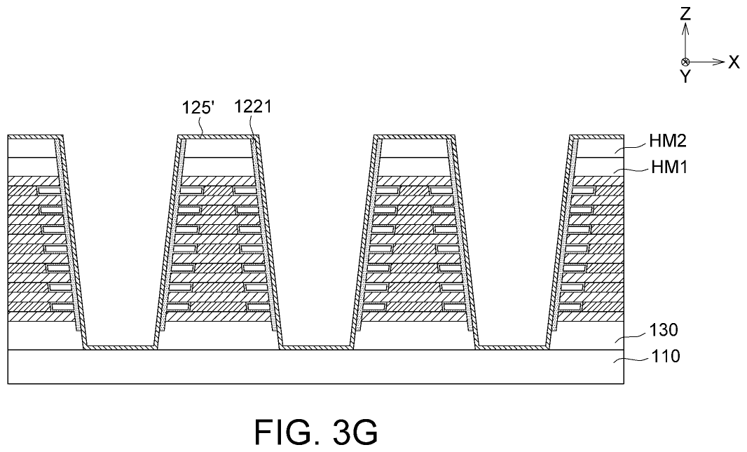

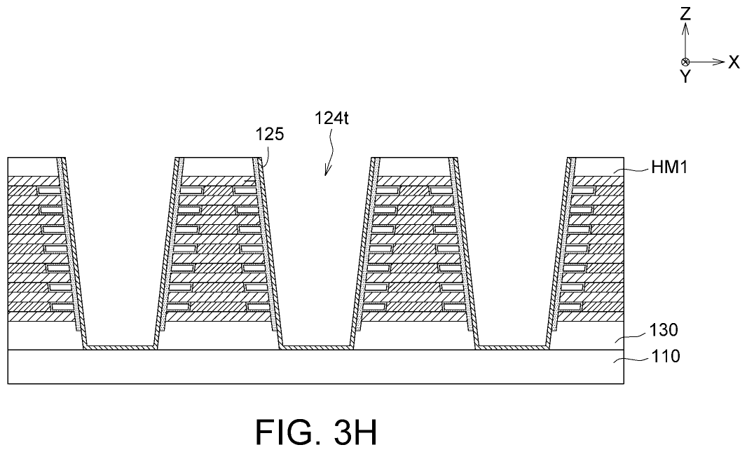

Referring to FIGS. 3A_a to 3H, FIGS. 3A_a to 3H illustrate schematic diagrams of manufacturing processes of the semiconductor device 100 in FIG. 1, wherein FIG. 3A_a illustrates a schematic diagram of a stacked structure over the MEOL structure 110, FIG. 3A_b illustrates a schematic diagram of a cross-sectional view of the stacked structure in FIG. 3A_a, FIG. 3B_a illustrates a schematic diagram of forming the trench 124t on the stacked structure, and FIG. 3B_b illustrates a schematic diagram of a cross-sectional view of the stacked structure in FIG. 3B_a.

As illustrated in FIGS. 3A_a and 3A_b, the first etching stop layer 130 is formed on the MEOL structure 110 by, for example, deposition such as PVD, CVD, ALD, or spin on. Then, a stacked structure is formed over the first etching stop layer 130 by, for example, deposition, such as spin, CVD, PVD, ALD, etc. Furthermore, the stacked structure includes a plurality of first sub-dielectric layer material 1211′ and a plurality of second sub-dielectric layer material 1212′, wherein one of the second sub-dielectric layers 1212′ is formed between adjacent two of the first sub-dielectric layers 1211′. Then, a first hard mask HM1 is formed over the stacked structure, and a second hard mask HM2 is formed over the first hard mask HM1 by using, for example, deposition. In addition, the first hard mask HM1 and/or the second hard mask HM2 may be formed of a material including TIN, TiO, W, W_{d}C, H_{f}O, ZrO, ZnO, TiZrO, SiC, SiO₂, SiOC, SiN, SiCN, SION, SiOCN, AlOx, AlON, etc. The first hard mask HM1 and/or the second hard mask HM2 may have a thickness ranging between 30 Å and 500 Å.

In an embodiment, each first sub-dielectric layer material 1211′ is formed from a material different from that of the second sub-dielectric layer material 1212′. The first sub-dielectric layer material 1211′ may be formed of one of SiC, SiO₂, SiOC, SiN, SiCN, SiON and SiOCN, and the second sub-dielectric layer material 1212′ may be formed of another of SiC, SiO₂, SiOC, SiN, SiCN, SiON and SiOCN. In addition, the first sub-dielectric layer material 1211′ and/or the second sub-dielectric layer material 1212′ may have a thickness ranging between 30 Å and 1000 Å.

As illustrated in FIGS. 3B_a and 3B_b, the first hard mask HM1 and the second hard mask HM2 may be patterned to define the region of the trench 124t. Then, at least one trench 124t passing through the stacked structure through the patterned first hard mask HM1 and second hard mask HM2 by, for example, etching, wherein the trench 124t stops at the first etching stop layer 130. In the present embodiment, the first etching stop layer 130 may serve as the M0 ESL.

After the trench 124t is formed, a portion of the first sub-dielectric layer material 1211′ and a portion of the second sub-dielectric layer material 1212′ are removed, and a remaining portion of the first sub-dielectric layer material 1211′ forms the first sub-dielectric layer 1211, and a remaining portion of the second sub-dielectric layer material 1212′ forms the second sub-dielectric layer 1212. The trench 124t has an inner sidewall including the lateral surface 1211s of each first sub-dielectric layer 1211, a lateral surface 1212s of the second sub-dielectric layer 1212 and an inner sidewall 130w of the first etching stop layer 130.

In addition, due to the first etching stop layer 130, each formed trench 124t may stop at the first etching stop layer 130, and accordingly have an approximately the same depth (for example, in Z axis).

As illustrated in FIG. 3C, a portion 1212p of the second sub-dielectric layer 1212 is removed by, for example, etching. The second sub-dielectric layer 1212 may be etched by using etcher (for example, ICP, CCP, or remote plasma) with etch gases: CH₄, CH₃F, CH₂F₂, CHF₃, C4F₈, C₄F₆, CF₄, NF₃, NH₃, H₂, HF, HBr, CO, CO₂, O₂, BCl₃, Cl₂, N₂, He, Ne, Ar, etc. with pressure 0.2 mT to 120 mT at 0° C.˜180° C., power 0 W˜3000 W and bias 0 V to 1200V, or be etched by wet clean remove. Due to the second sub-dielectric layer 1212 having the material different from that of the first sub-dielectric layer 1211, a portion of the second sub-dielectric layer 1212 may be removed, by selective etching for the second sub-dielectric layer 1212, to form the recess 121r, while most of material of the first sub-dielectric layer 1211 may be retained. The recess 121r is recessed with respect to the lateral surface 1211s. In addition, due to the second sub-dielectric layer 1212 being formed between adjacent two of the first sub-dielectric layers 1211, the second width W2 of the second sub-dielectric layer 1212 or the size of the air gap 121a formed subsequently may be controllable by, for example, etching.

As illustrated in FIG. 3D, a spacer material 122′ is formed over the inner sidewall of the trench 124t, a bottom portion of the trench 124t and a top portion of the trench 124t by, for example, deposition, such as spin, CVD, PVD, ALD, etc. The spacer material 122′ includes a first covering portion 1221′, a second covering portion 1222, a top covering portion 1223′ and a bottom covering portion 1224′, wherein the first covering portion 1221′ covers the entire lateral surface 1211s of each first sub-dielectric layer 1211, the second covering portion 1222 is formed within the recess 121r and covers the inner sidewall of the recess 121r, the top covering portion 1223′ covers the top portion of the second hard mask HM2, and the bottom covering portion 1224′ covers the first etching stop layer 130 exposed from the trench 124t. Due to the recess 121r, the first covering portion 1221′ has at least one cave 1221r′ conforming to the recess 121r. The lateral surface of the first covering portion 1221′ is, for example, a wavy surface.

As illustrated in FIG. 3E, a portion of the first covering portion 1221′, the top covering portion 1223′ and the bottom covering portion 1224′ in FIG. 3D are removed by, for example, etching. After etching, the second hard mask HM2 and the first etching stop layer 130 are exposed, and the caves 1221r′ in FIG. 3D are removed. After etching, a remaining portion of the first covering portion 1221′ forms the first covering portion 1221 having a lateral surface 1221s which is flatter compared to the lateral surface (wavy surface) of the first covering portion 1221′ in FIG. 3D.

As illustrated in FIG. 3F, a portion 131 of the first etching stop layer 130 exposed from the trench 124t in FIG. 3E is removed to form a deeper trench 124t for exposing the MEOL structure 110 by, for example, etching.

As illustrated in FIG. 3G, a barrier material 125′ covering the second hard mask HM2, the first covering portion 1221, the first etching stop layer 130 and the MEOL structure 110 is formed by using, for example, deposition.

As illustrated in FIG. 3H, a portion of the barrier material 125′, a portion of the first covering portion 1221 and the second hard mask HM2 in FIG. 3G are removed by using, for example, a CMP (Chemical-Mechanical Planarization). After CMP, the barrier material 125′ forms at least one barrier 125 as illustrated in FIG. 1.

Then, the conductive portion 123 in FIG. 1 fills the trench 124t in FIG. 3H to form the semiconductor device 100 in FIG. 1 by using deposition and CMP, wherein the conductive portion 123 is electrically connected to the MEOL structure 110. Due to each formed trench 124t having the approximately the same depth (for example, in Z axis), the conductive portions 123 which fill the trenches 124t accordingly have the approximately the same lengths (for example, in Z axis). In the present embodiment, the conductive portion 123 is formed after the air gap 121a is formed, and thus the conductive portion 123 is not damaged by process of forming the air gap 121a.

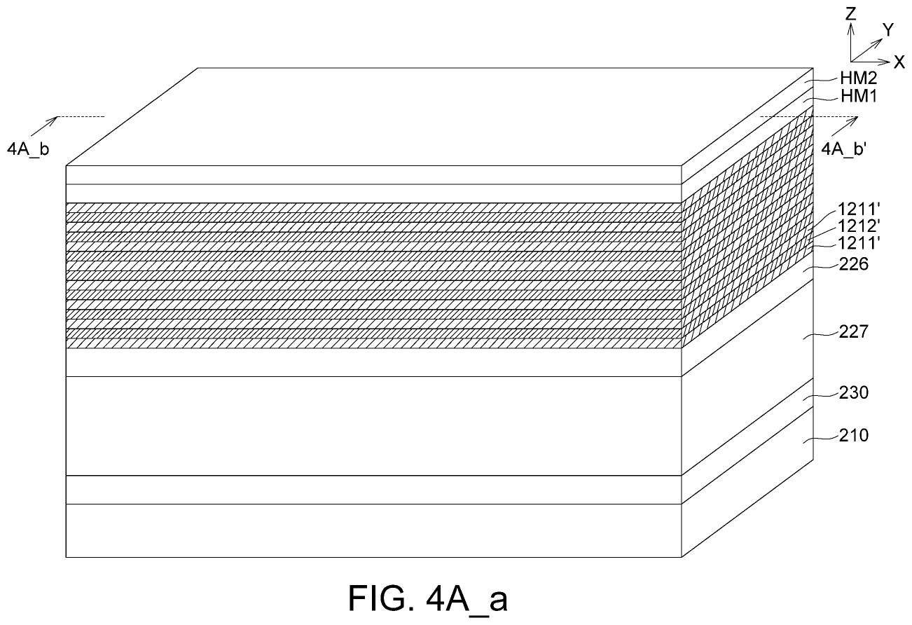

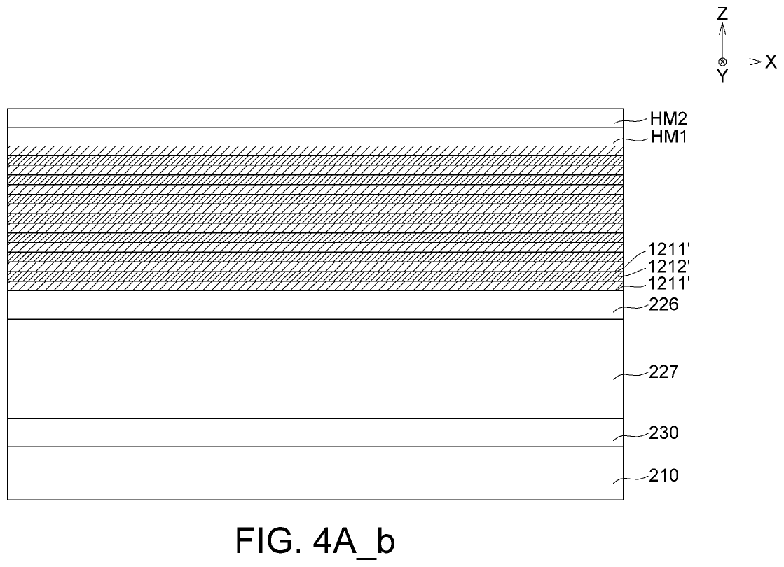

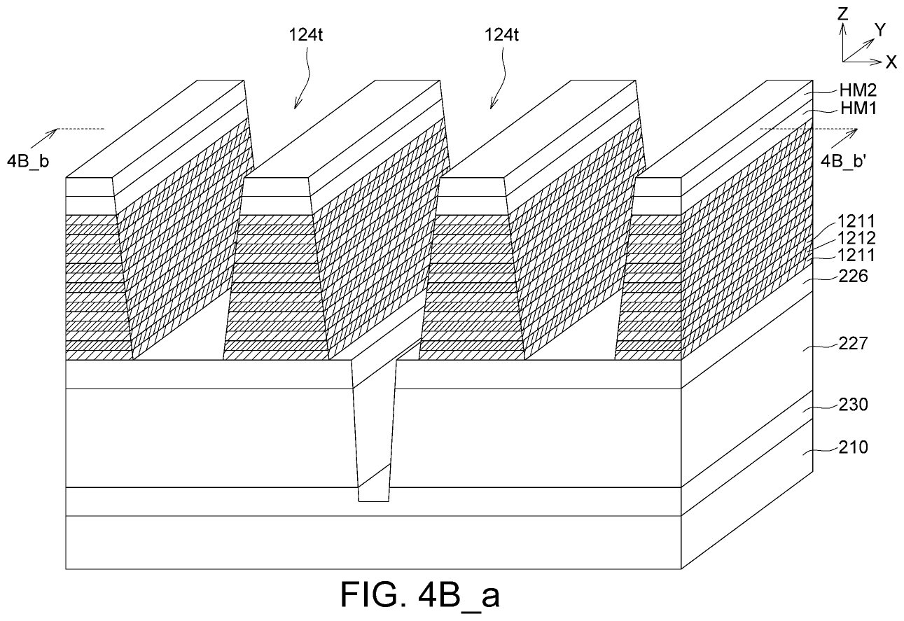

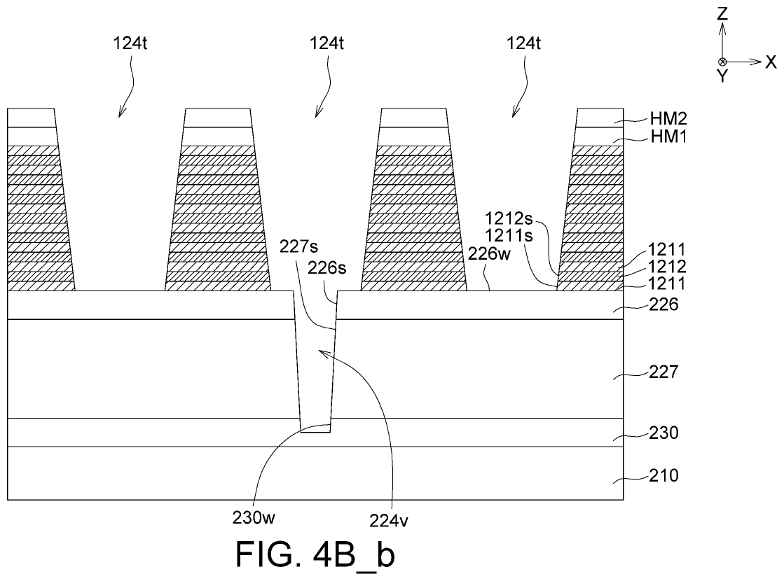

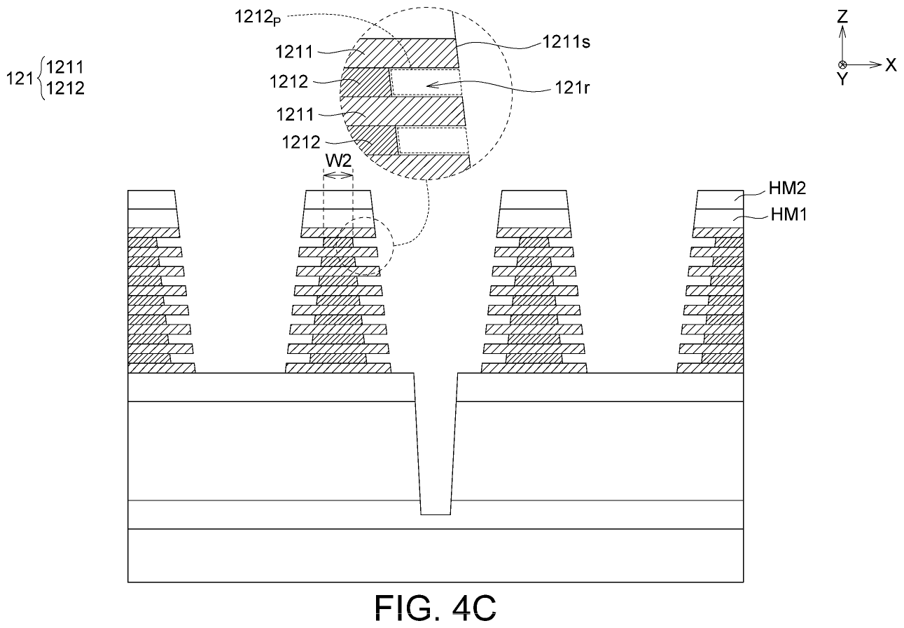

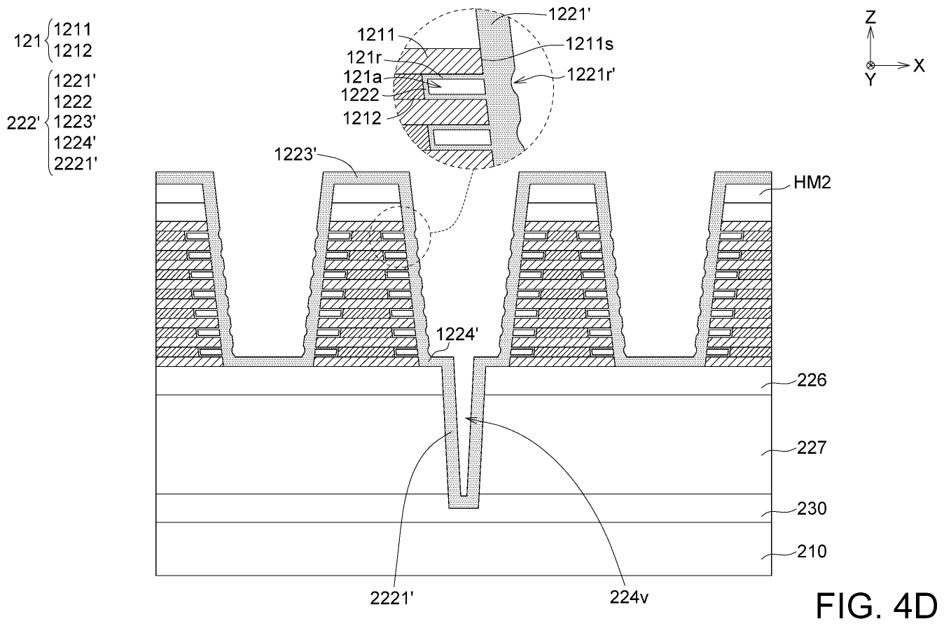

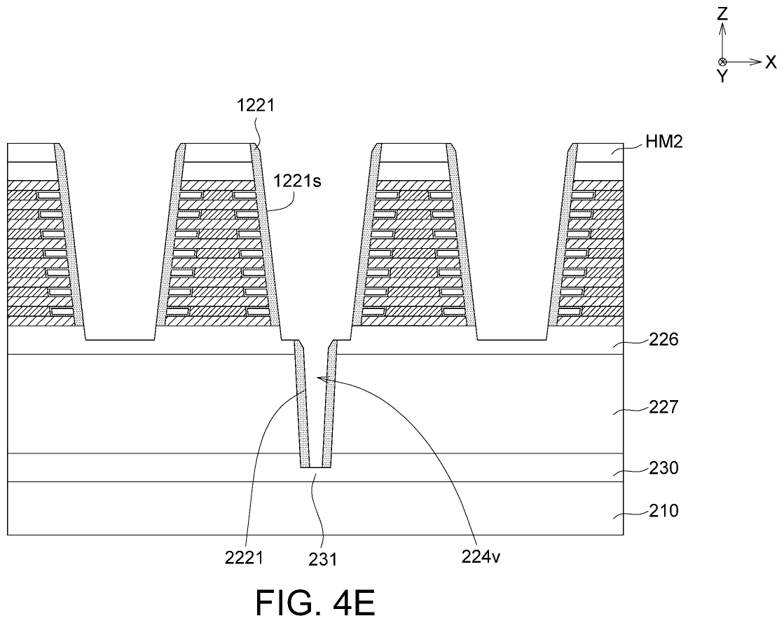

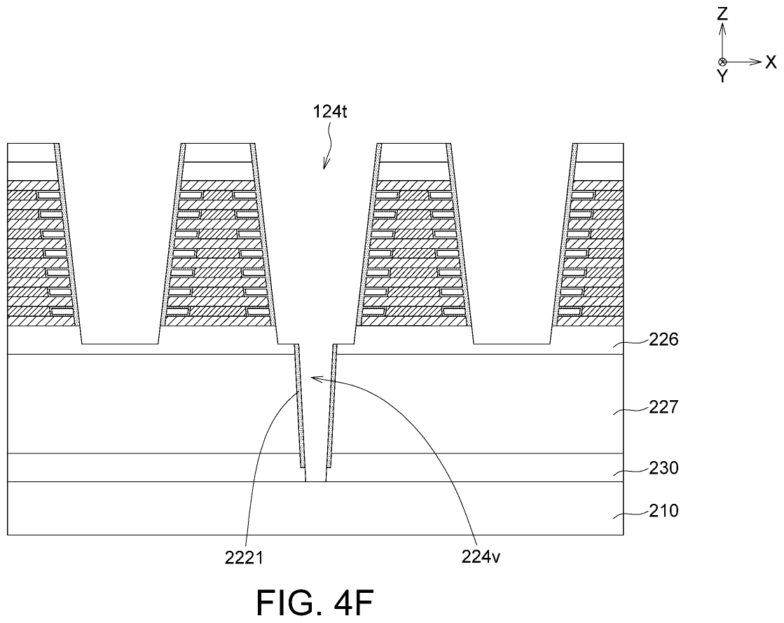

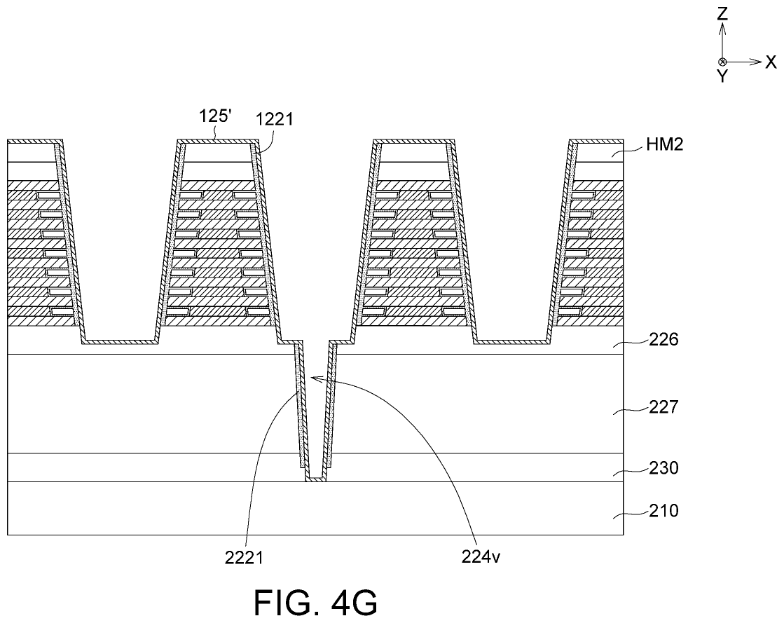

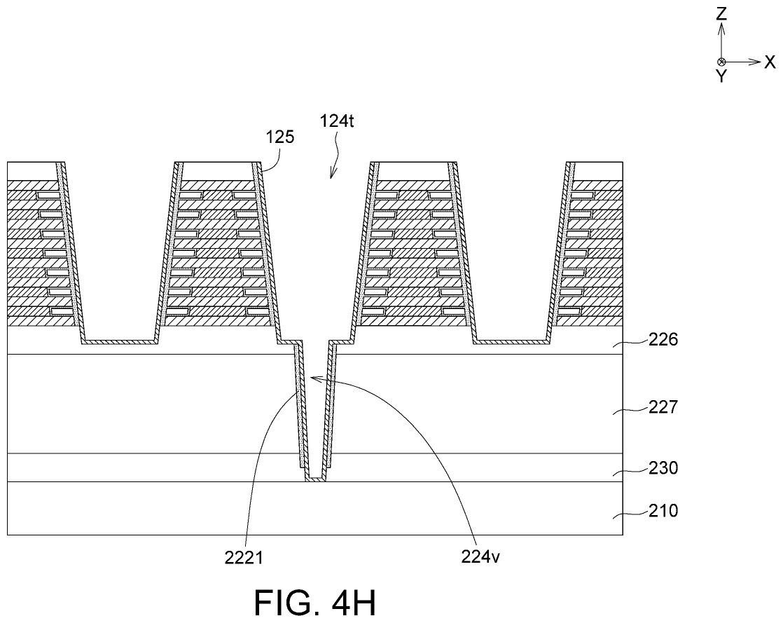

Referring to FIGS. 4A_a to 4H, FIGS. 4A_a to 4H illustrate schematic diagrams of manufacturing processes of the semiconductor device 200 in FIG. 2, wherein FIG. 4A_a illustrates a schematic diagram of a stacked structure over the conductive layer 210, FIG. 4A_b illustrates a schematic diagram of a cross-sectional view of the stacked structure in FIG. 4A_a, FIG. 4B_a illustrates a schematic diagram of forming the trench 124t on the stacked structure, and FIG. 4B_b illustrates a schematic diagram of a cross-sectional view of the stacked structure in FIG. 4B_a.

As illustrated in FIGS. 4A_a and 4A_b, the first etching stop layer 230 is formed on the conductive layer 210 by, for example, deposition. The first etching stop layer 230 may be formed by, for example, spin on, CVD, PVD, ALD, etc. at 20° C. to 400° C. In addition, the first etching stop layer 230 has a thickness ranging between 10 Å and 1000 Å. Then, the second dielectric layer 227 is formed over the first etching stop layer 230 by, for example, deposition, such as spin on, CVD, PVD, ALD, etc. Then, the second etching stop layer 226 is formed over the second dielectric layer 227 by, for example, deposition, such as spin on, CVD, PVD, ALD, etc. Then, a stacked structure is formed over the first etching stop layer 230 by, for example, deposition, such as spin, CVD, PVD, ALD, etc. Furthermore, the stacked structure includes a plurality of first sub-dielectric layer material 1211′ and a plurality of second sub-dielectric layer material 1212′, wherein one of the second sub-dielectric layers 1212′ is formed between adjacent two of the first sub-dielectric layers 1211′. Then, the first hard mask HM1 is formed over the stacked structure, and the second hard mask HM2 is formed over the first hard mask HM1. Although not illustrated, the MEOL structure may be formed first, and then the conductive layer 210 is formed above the MEOL structure.

As illustrated in FIGS. 4B_a and 4B_b, the first hard mask HM1 and the second hard mask HM2 may be patterned to define the region of the trench 124t. Then, at least one trench 124t passing through the stacked structure, through the patterned first hard mask HM1 and second hard mask HM2, is formed by, for example, etching wherein the trench 124t stops at the second etching stop layer 226. In addition, the through hole 224v passing through the second etching stop layer 226, the second dielectric layer 227 and a portion of the first etching stop layer 230 from the trench 124t may be formed.

After the trench 124t is formed, a portion of the first sub-dielectric layer material 1211′ and a portion of the second sub-dielectric layer material 1212′ are removed, and a remaining portion of the first sub-dielectric layer material 1211′ forms the first sub-dielectric layer 1211, and a remaining portion of the second sub-dielectric layer material 1212′ forms the second sub-dielectric layer 1212.

As illustrated in FIG. 4B_b, the trench 124t has the inner sidewall including the lateral surface 1211s of the first sub-dielectric layer 1211, the lateral surface 1212s of the second sub-dielectric layer 1212 and the inner sidewall 226w of the second etching stop layer 226. The through hole 224v has an inner sidewall including a lateral surface 226s of the second etching stop layer 226, a lateral surface 227s of the second dielectric layer 227 and an inner sidewall 230w of the first etching stop layer 230.

In addition, due to the second etching stop layer 226, each formed trench 124t may stop at the second etching stop layer 226, and accordingly each trench 124t has the approximately the same depth (for example, in Z axis).

As illustrated in FIG. 4C, the portion 1212p of the second sub-dielectric layer 1212 is removed by, for example, etching. The second sub-dielectric layer 1212 may be etched by using etcher (for example, ICP, CCP, or remote plasma) with etch gases: CH₄, CH₃F, CH₂F₂, CHF₃, C₄F₈, C₄F₆, CF₄, NF₃, NH₃, H₂, HF, HBr, CO, CO₂, O₂, BCl₃, Cl₂, N₂, He, Ne, Ar, etc. with pressure 0.2 mT to 120 mT at 0° C.˜180° C., power 0 W˜3000 W and bias 0 V to 1200V, or be etched by wet clean removed. Due to the second sub-dielectric layer 1212 having the material different from that of the first sub-dielectric layer 1211, a portion of the second sub-dielectric layer 1212 may be removed, by selective etching for the second sub-dielectric layer 1212, to form the recess 121r, while most of material of the first sub-dielectric layer 1211 may be retained. The recess 121r is recessed with respect to the lateral surface 1211s. In addition, due to the second sub-dielectric layer 1212 being formed between adjacent two of the first sub-dielectric layers 1211, the second width W2 of the second sub-dielectric layer 1212 or the size of the air gap 121a formed subsequently may be controllable by, for example, etching.

As illustrated in FIG. 4D, a spacer material 122′ is formed over the inner sidewall of the trench 124t, a bottom portion of the trench 124t, a top portion of the trench 124t and the inner sidewall of the through hole 224v by, for example, deposition, such as spin, CVD, PVD, ALD, etc. The spacer material 122′ includes the first covering portion 1221′, the second covering portion 1222, a third covering portion 2221′, the top covering portion 1223′ and the bottom covering portion 1224′, wherein the first covering portion 1221′ covers the entire lateral surface 1211s of each first sub-dielectric layer 1211, the second covering portion 1222 is formed within the recess 121r and covers the inner sidewall of the recess 121r, the third covering portion 2221′ covers an inner sidewall of the through hole 224v, the top covering portion 1223′ covers the top portion of the trench 124t, and the bottom covering portion 1224′ covers the second etching stop layer 226 exposed from the trench 124t. Due to the recess 121r, the first covering portion 1221′ has at least one cave 1221r′ conforming to the recess 121r. The lateral surface of the first covering portion 1221′ is, for example, a wavy surface.

As illustrated in FIG. 4E, a portion of the first covering portion 1221′, the top covering portion 1223′, the bottom covering portion 1224′ and a portion of the third covering portion 2221′ in FIG. 4D are removed by, for example, etching. After etching, the second hard mask HM2, second etching stop layer 226 and the first etching stop layer 230 are exposed, and the caves 1221r′ in FIG. 4D are removed. After etching, a remaining portion of the first covering portion 1221′ forms the first covering portion 1221 having the lateral surface 1221s which is flatter compared to the lateral surface (wavy surface) of the first covering portion 1221′ in FIG. 4D.

As illustrated in FIG. 4F, a portion 231 of the first etching stop layer 230 exposed from the through hole 224v in FIG. 4E is removed to form a deeper through hole 224v for exposing the conductive layer 210 by, for example, etching.

As illustrated in FIG. 4G, a barrier material 125′ covering the second hard mask HM2, the first covering portion 1221, the second etching stop layer 226, the third covering portion 2221, the first etching stop layer 230 and the conductive layer 210 is formed by using, for example, deposition.

As illustrated in FIG. 4H, a portion of the barrier material 125′, a portion of the first covering portion 1221 and the second hard mask HM2 in FIG. 4G are removed by using, for example, a CMP. After CMP, the barrier material 125′ forms at least one barrier 125 as illustrated in FIG. 2.

Then, the conductive portion 123 in FIG. 2 fills the trench 124t and the through hole 224v in FIG. 4H to form the semiconductor device 200 in FIG. 2 by using deposition and CMP, wherein the conductive portion 123 is electrically connected to the conductive layer 210. Due to each trench 124t having the approximately the same depth (for example, in Z axis) and each through hole 224v having the approximately the same depth (for example, in Z axis), the conductive portions 123 which fill the trenches 124t and the through holes 224v accordingly have the approximately the same lengths (for example, in Z axis). In the present embodiment, the conductive portion 123 is formed after the air gap 121a is formed, and thus the conductive portion 123 is not damaged by process of forming the air gap 121a.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a MEOL structure and a BEOL structure. The BEOL structure is formed over the MEOL structure and includes a dielectric layer, a spacer and a plurality of conductive portions. The first dielectric layer has a lateral surface and a recess, wherein the recess is recessed with respect to the lateral surface. The recess is sealed by the spacer to form an air gap. The conductive portions are separated from each other by air gap. The air gap may increase the electrical isolation between two conductive components. In comparison with the conventional structure, the air gap in the present embodiment may reduce parasitic capacitance, and accordingly it may obtain better electrical performance (such as better reliability, reducing propagation delay and extra noise, etc.).

Example embodiment 1: a semiconductor device includes a MEOL structure and a BEOL structure. The BEOL structure is formed over the MEOL structure and includes a first dielectric layer, a spacer and a conductive portion. The first dielectric layer has a lateral surface and a recess, wherein the recess is recessed with respect to the lateral surface. The spacer is formed the lateral surface and covers an opening of the recess. The conductive portion is formed adjacent to the spacer.

Example embodiment 2 based on Example embodiment 1: the first dielectric layer includes a plurality of first sub-dielectric layers and a second sub-dielectric layer. Each first sub-dielectric layer has the lateral surface. The second sub-dielectric layer is formed between adjacent two of the first sub-dielectric layers. The recess extends from the lateral surfaces of adjacent two of the first sub-dielectric layers to the second sub-dielectric layer.

Example embodiment 3 based on Example embodiment 2: each first sub-dielectric layer is formed of a material different from that of the second sub-dielectric layer.

Example embodiment 4 based on Example embodiment 1: the first dielectric layer includes a first sub-dielectric layer having a first width and a second sub-dielectric layer stacked to the first sub-dielectric layer and having a second width. The first width is greater than the second width.

Example embodiment 5 based on Example embodiment 1: the semiconductor device further includes a first etching stop layer. The first dielectric layer is formed over the first etching stop layer.

Example embodiment 6 based on Example embodiment 1: the semiconductor device further includes a trench passing through the first dielectric layer and extending to the MEOL structure. The conductive portion fills the trench.

Example embodiment 7 based on Example embodiment 1: the semiconductor device further includes a first etching stop layer, a second etching stop layer and a second dielectric layer. The second dielectric layer is formed between the first etching stop layer and the second etching stop layer.

Example embodiment 8 based on Example embodiment 7: the semiconductor device further includes a trench, a conductive layer and a through hole. The trench passes through the first dielectric layer and extends to the second etching stop layer. The conductive layer is formed above the MEOL structure. The through hole extends to the conductive layer form the trench. The conductive portion fills the trench and the through hole.

Example embodiment 9 based on Example embodiment 7: the semiconductor device further includes a conductive layer and a through hole. The conductive layer is formed above the MEOL structure The through hole extends to the MEOL structure form the trench and passes through the second etching stop layer and the second dielectric layer.

Example embodiment 10: a semiconductor device includes a MEOL structure and a BEOL structure. The BEOL structure is formed over the MEOL structure and includes a first dielectric layer, a spacer and a plurality of conductive portions. The first dielectric layer has a plurality of air gaps, wherein each air gap extends in a first direction, and the air gaps are arranged in a second direction perpendicular to the first direction. The spacer is formed the lateral surface and seals each air gap. The conductive portions are separated by the air gaps.

Example embodiment 11 based on Example embodiment 10: the first dielectric layer includes a plurality of first sub-dielectric layers and a second sub-dielectric layer. Each first sub-dielectric layer has the lateral surface. The second sub-dielectric layer is formed between adjacent two of the first sub-dielectric layers. The recess extends from the lateral surfaces of adjacent two of the first sub-dielectric layers to the second sub-dielectric layer.

Example embodiment 12 based on Example embodiment 11: each first sub-dielectric layer is formed of a material different from that of the second sub-dielectric layer.

Example embodiment 13 based on Example embodiment 10: the first dielectric layer includes a first sub-dielectric layer and a second sub-dielectric layer. The first sub-dielectric layer has a first width. The second sub-dielectric layer is stacked to the first sub-dielectric layer and having a second width. The first width is greater than the second width.

Example embodiment 14 based on Example embodiment 10: semiconductor device further includes a trench passing through the first dielectric layer and extending to the MEOL structure. The conductive portion fills the trench.

Example embodiment 15: a manufacturing method for a semiconductor device includes the following steps: forming a MEOL structure; and forming a BEOL structure over the MEOL structure including: forming a first dielectric layer having a lateral surface and a recess, wherein the recess is recessed with respect to the lateral surface; forming a spacer on the lateral surface, wherein the spacer covers an opening of the recess; and forming a conductive portion adjacent to the spacer.

Example embodiment 16 based on Example embodiment 15: forming the first dielectric layer having the lateral surface and the recess includes: forming a plurality of first sub-dielectric layers and a second sub-dielectric layer, wherein the second sub-dielectric layer is formed between adjacent two of the first sub-dielectric layers; and removing a portion of the second sub-dielectric layer to form the recess, wherein the recess extends from the lateral surfaces of adjacent two of the first sub-dielectric layers to the second sub-dielectric layer.

Example embodiment 17 based on Example embodiment 16: in forming the plurality of first sub-dielectric layers and the second sub-dielectric layer, each first sub-dielectric layer is formed from a material different from that of the second sub-dielectric layer.

Example embodiment 18 based on Example embodiment 15: forming the first dielectric layer having the lateral surface and the recess further including: forming a trench to pass through the first dielectric layer; and forming the recess in the first dielectric layer through the trench.

Example embodiment 19 based on Example embodiment 15: forming the first dielectric layer having the lateral surface and the recess further includes: forming a trench to pass through the first dielectric layer, wherein the trench stops at a first etching stop layer; and forming the recess in the first dielectric layer through the trench. After forming the spacer on the lateral surface, the manufacturing method further includes: removing a portion of a first etching stop layer to expose the MEOL structure.

Example embodiment 20 based on Example embodiment 15: forming the BEOL structure over the MEOL structure further includes: forming a first etching stop layer on a conductive layer; forming a second dielectric layer on the first etching stop layer; and forming a second etching stop layer on the second dielectric layer. Forming the first dielectric layer having the lateral surface and the recess further includes: forming a trench to pass through the first dielectric layer, wherein the trench stops at the second etching stop layer. The manufacturing method further includes: forming a through hole, from the trench, to pass through the second etching stop layer, the second dielectric layer and the first etching stop layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a MEOL (Middle End of Line) structure; and
a BEOL (Back End of Line) structure formed over the MEOL structure, and comprising:
a first dielectric layer having a lateral surface and a recess, wherein the recess is recessed with respect to the lateral surface;
a spacer formed the lateral surface and covering an opening of the recess; and
a conductive portion formed adjacent to the spacer.

2. The semiconductor device as claimed in claim 1, wherein the first dielectric layer comprises:
a plurality of first sub-dielectric layers each having the lateral surface; and
a second sub-dielectric layer formed between adjacent two of the first sub-dielectric layers;
wherein the recess extends from the lateral surfaces of adjacent two of the first sub-dielectric layers to the second sub-dielectric layer.

3. The semiconductor device as claimed in claim 2, wherein each first sub-dielectric layer is formed of a material different from that of the second sub-dielectric layer.

4. The semiconductor structure as claimed in claim 1, wherein the first dielectric layer comprises:
a first sub-dielectric layer having a first width; and
a second sub-dielectric layer stacked to the first sub-dielectric layer and having a second width;
wherein the first width is greater than the second width.

5. The semiconductor device as claimed in claim 1, further comprising:
a first etching stop layer;
wherein the first dielectric layer is formed over the first etching stop layer.

6. The semiconductor device as claimed in claim 1, further comprising:
a trench passing through the first dielectric layer and extending to the MEOL structure;
wherein the conductive portion fills the trench.

7. The semiconductor device as claimed in claim 1, further comprising:
a first etching stop layer;
a second etching stop layer; and
a second dielectric layer formed between the first etching stop layer and the second etching stop layer.

8. The semiconductor device as claimed in claim 7, further comprising:
a trench passing through the first dielectric layer and extending to the second etching stop layer;
a conductive layer formed above the MEOL structure; and
a through hole extending to the conductive layer form the trench;
wherein the conductive portion fills the trench and the through hole.

9. The semiconductor device as claimed in claim 7, further comprising:
a conductive layer formed above the MEOL structure; and
a through hole extending to the conductive layer form the trench and passing through the second etching stop layer and the second dielectric layer.

10. A semiconductor device, comprising:
a MEOL structure; and
a BEOL structure formed over the MEOL structure, comprising:
a first dielectric layer having a plurality of air gaps, wherein each air gap extends in a first direction, and the air gaps are arranged in a second direction perpendicular to the first direction;
a spacer formed the lateral surface and sealing each air gap; and
a plurality of conductive portions separated by the air gaps.

11. The semiconductor device as claimed in claim 10, wherein the first dielectric layer comprises:
a plurality of first sub-dielectric layers each having the lateral surface; and
a second sub-dielectric layer formed between adjacent two of the first sub-dielectric layers;
wherein the recess extends from the lateral surfaces of adjacent two of the first sub-dielectric layers to the second sub-dielectric layer.

12. The semiconductor device as claimed in claim 11, wherein each first sub-dielectric layer is formed of a material different from that of the second sub-dielectric layer.

13. The semiconductor structure as claimed in claim 10, wherein the first dielectric layer comprises:
a first sub-dielectric layer having a first width; and
a second sub-dielectric layer stacked to the first sub-dielectric layer and having a second width;
wherein the first width is greater than the second width.

14. The semiconductor device as claimed in claim 10, further comprising:
a trench passing through the first dielectric layer and extending to the MEOL structure;
wherein the conductive portion fills the trench.

15. A manufacturing method for a semiconductor device, comprising:
forming a MEOL structure; and
forming a BEOL structure over the MEOL structure, comprising:
forming a first dielectric layer having a lateral surface and a recess, wherein the recess is recessed with respect to the lateral surface;
forming a spacer on the lateral surface, wherein the spacer covers an opening of the recess; and
forming a conductive portion adjacent to the spacer.

16. The manufacturing method as claimed in claim 15, wherein forming the first dielectric layer having the lateral surface and the recess comprises:
forming a plurality of first sub-dielectric layers and a second sub-dielectric layer, wherein the second sub-dielectric layer is formed between adjacent two of the first sub-dielectric layers; and
removing a portion of the second sub-dielectric layer to form the recess, wherein the recess extends from the lateral surfaces of adjacent two of the first sub-dielectric layers to the second sub-dielectric layer.

17. The manufacturing method as claimed in claim 16, wherein in forming the plurality of first sub-dielectric layers and the second sub-dielectric layer, each first sub-dielectric layer is formed from a material different from that of the second sub-dielectric layer.

18. The manufacturing method as claimed in claim 15, wherein forming the first dielectric layer having the lateral surface and the recess further comprises:
forming a trench to pass through the first dielectric layer; and
forming the recess in the first dielectric layer through the trench.

19. The manufacturing method as claimed in claim 15, wherein forming the first dielectric layer having the lateral surface and the recess further comprises:
forming a trench to pass through the first dielectric layer, wherein the trench stops at a first etching stop layer; and
forming the recess in the first dielectric layer through the trench;
wherein after forming the spacer on the lateral surface, the manufacturing method further comprises:
removing a portion of a first etching stop layer to expose the MEOL structure.

20. The manufacturing method as claimed in claim 15, wherein forming the BEOL structure over the MEOL structure further comprises:
forming a first etching stop layer on a conductive layer;
forming a second dielectric layer on the first etching stop layer; and
forming a second etching stop layer on the second dielectric layer;
wherein forming the first dielectric layer having the lateral surface and the recess further comprises:
forming a trench to pass through the first dielectric layer, wherein the trench stops at the second etching stop layer;
wherein the manufacturing method further comprises:
forming a through hole, from the trench, to pass through the second etching stop layer, the second dielectric layer and the first etching stop layer.
